(19) United States
(12) Patent Application Publication
(10) Pub. No.: US 2012/0141667 A1
(43) Pub. Date: Jun. 7, 2012

(54) METHODS FOR FORMING BARRIER/SEED LAYERS FOR COPPER INTERCONNECT STRUCTURES

(75) Inventors: HOON KIM, San Jose, CA (US); SANG HO YU, Cupertino, CA (US); SESHADRI GANGULI, Sunnyvale, CA (US)

(73) Assignee: APPLIED MATERIALS, INC., Santa Clara, CA (US)

(21) Appl. No.: 13/315,906

(22) Filed: Dec. 9, 2011

Related U.S. Application Data
(63) Continuation-in-part of application No. 13/167,001, filed on Jun. 23, 2011.
(60) Provisional application No. 61/365,082, filed on Jul. 16, 2010.

(51) Int. Cl. C23C 16/06; C25D 5/02

(52) U.S. Cl. 427/123; 205/131

(57) ABSTRACT

Methods for forming barrier/seed layers for interconnect structures are provided herein. In some embodiments, a method of processing a substrate having an opening formed in a first surface of the substrate, the opening having a sidewall and a bottom surface, the method may include forming a layer comprising manganese (Mn) and at least one of ruthenium (Ru) or cobalt (Co) on the sidewall and the bottom surface of the opening, the layer having a first surface adjacent to the sidewall and bottom surface of the opening and a second surface opposite the first surface, wherein the second surface comprises predominantly at least one of ruthenium (Ru) or cobalt (Co) and wherein a predominant quantity of manganese (Mn) in the layer is not disposed proximate the second surface; and depositing a conductive material on the layer to fill the opening.

### CROSS-REFERENCE TO RELATED APPLICATIONS

This application is a continuation in part of U.S. patent application Ser. No. 13/167,001, filed Jun. 23, 2011, which claims benefit of United States provisional patent application Ser. No. 61/365,082, filed Jul. 16, 2010, each of which are herein incorporated by reference.

### FIELD

Embodiments of the present invention generally relate to methods of processing substrates, and specifically to methods for forming a barrier/seed layers for interconnect structures.

### BACKGROUND

As device nodes get smaller (for example, approaching dimensions of about 22 nm or less), manufacturing challenges become more apparent. For example, the combined thickness of barrier and seed layers of typical materials deposited in an opening prior to filling the opening, for example via electroplating, to form an interconnect structure may result in reduced efficiency of the electroplating process, reduced process throughput and/or yield, or the like.

Ruthenium, deposited for example by chemical vapor deposition (CVD), has become a promising candidate as a seed layer for a copper interconnect. However, ruthenium by itself cannot be a copper barrier and barrier layers such as TaN/Ta are still needed prior to ruthenium deposition. Alternatively, copper-manganese, deposited for example by physical vapor deposition (PVD), self-aligned barrier schemes have also gained in popularity as a desirable approach to the barrier solution. However, the inventors have observed that these two schemes each have manufacturability difficulties.

For CVD ruthenium, the deposition rate is very slow without O₂ as reducing gas. However, the O₂ gas tends to oxidize the tantalum-based barrier layer, resulting in increase via resistance. Therefore, with TaN/Ta as barrier, throughput with CVD ruthenium will be very slow. In addition, deposition of ruthenium without O₂ also results in high carbon contaminated ruthenium films, which also increases line/via resistance. A high resistivity ruthenium film is not adequate for a seed layer, which is the main merit of the ruthenium seed layer.

With respect to the Cu—Mn process (a physical vapor deposition, or PVD, process), copper can diffuse into the oxide layer, especially low-k oxide, during the deposition steps, causing reliability issues.

Thus, the inventors have provided improved methods for forming barrier/seed layers for interconnect structures.

### SUMMARY

Methods for forming barrier/seed layers for interconnect structures are provided herein. In some embodiments, a method of processing a substrate having an opening formed in a first surface of the substrate, the opening having a sidewall and a bottom surface, the method may include forming a layer comprising manganese (Mn) and at least one of ruthenium (Ru) or cobalt (Co) on the sidewall and the bottom surface of the opening, the layer having a first surface adjacent to the sidewall and bottom surface of the opening and a second surface opposite the first surface, wherein the second surface comprises predominantly at least one of ruthenium (Ru) or cobalt (Co) and wherein a predominant quantity of manganese (Mn) in the layer is not disposed proximate the second surface; and depositing a conductive material on the layer to fill the opening. The materials may be deposited by chemical vapor deposition (CVD) or by physical vapor deposition (PVD).

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart of a method for forming an interconnect structure in accordance with some embodiments of the present invention.

FIG. 2 depicts a side cross-sectional view of an interconnect structure formed in a substrate in accordance with some embodiments of the present invention.

FIG. 2A depicts a schematic representation of material content of a layer of an interconnect structure in accordance with some embodiments of the present invention.

FIGS. 3A-C depict schematic side views of a layer of an interconnect structure in accordance with some embodiments of the present invention.

FIGS. 4A-B depict the stages of fabrication of a layer of an interconnect structure in schematic side view in accordance with some embodiments of the present invention.

FIGS. 5A-B depict the stages of fabrication of a layer of an interconnect structure in schematic side view in accordance with some embodiments of the present invention.

FIG. 6 depicts a cluster tool suitable to perform methods for processing a substrate in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods for forming barrier/seed layers for interconnect structures are provided herein. As discussed below, the term barrier/seed layer is meant to include any of a layer comprising a seed layer deposited atop a barrier layer, or a layer comprising a barrier layer material and a seed layer material, wherein the barrier and seed layer materials may be deposited in any suitable manner, such as homogenously, graded, or the like within the layer to facilitate both barrier layer and seed layer properties. The inventive methods advantageous facilitate improved efficiency, process throughput, and device quality through one or more of reduced barrier/seed layer thickness, reduced barrier/seed layer resistance, or increased deposition rates. The inventive methods may be utilized with any device nodes, but may be particularly advantageous in device nodes of about 22 nm or less. Further, the inventive methods may be utilized with any type of interconnect structure or material, but may be particularly advantageous with interconnect structures formed by electroplating copper (Cu).

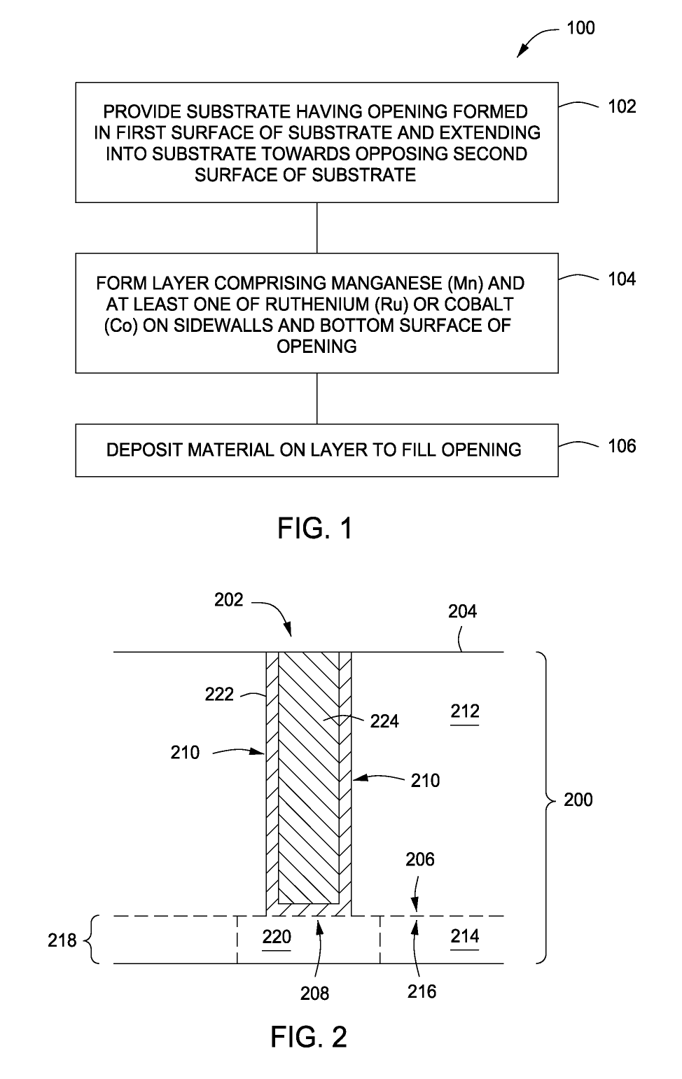

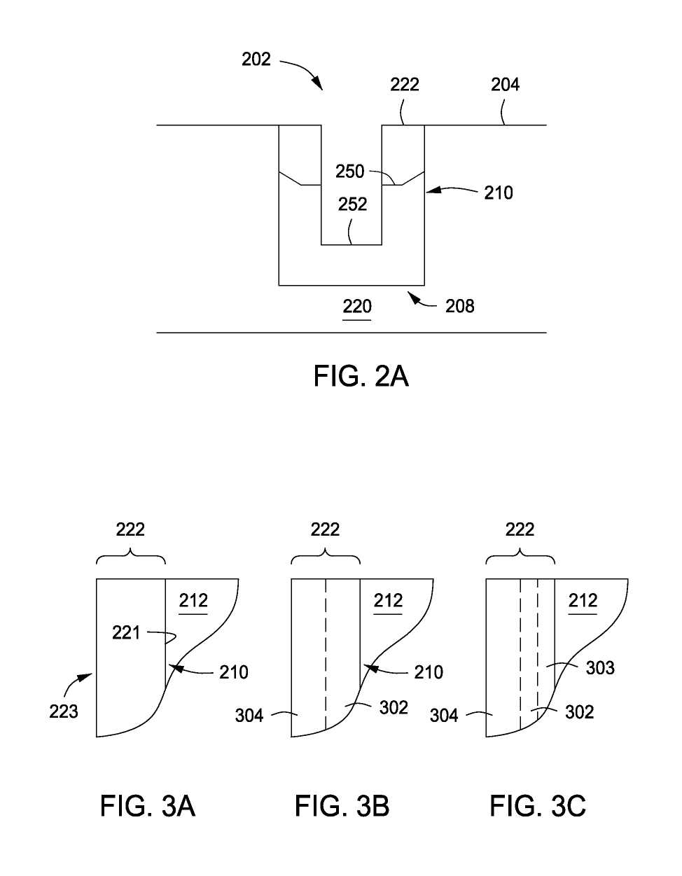

FIG. 1 depicts a flow chart of a method 100 for forming an interconnect structure in accordance with some embodiments of the present invention. The method 100 is described below with respect to an interconnect structure, as depicted in FIG. 2. The method 100 may be performed in any suitable process chambers configured for one or more of PVD, chemical vapor deposition (CVD), or atomic layer deposition (ALD). Exemplary processing systems that may be used to perform the invention methods disclosed herein may include, but are not limited to, those of the ENDURA®, CENTURA®, or PRODUCER® line of processing systems, and the ALPS® Plus or SIP ENCORE® PVD process chambers, all commercially available from Applied Materials, Inc., of Santa Clara, Calif. Other process chambers, including those from other manufacturers, may also be suitably used in connection with the teachings provided herein.

The method 100 generally begins at 102 by providing a substrate 200 having an opening 202, as depicted in FIG. 2. The opening 202 may be formed in a first surface 204 of the substrate 200 and extending into the substrate 200 towards an opposing second surface 206 of the substrate 200. The substrate 200 may be any suitable substrate having an opening formed therein. For example, the substrate 200 may comprise one or more of a dielectric material, Si, metals, or the like. In addition, the substrate 200 may include additional layers of materials or may have one or more completed or partially completed structures formed therein or thereon. For example, the substrate 200 may include a first dielectric layer 212, such as silicon oxide, low-k, or the like, and the opening 202 may be formed in the first dielectric layer 212. In some embodiments, the first dielectric layer 212 may be disposed atop a second dielectric layer 214, such as silicon oxide, silicon nitride, silicon carbide, or the like. A conductive material (e.g., 220) may be disposed in the second dielectric layer 214 and may be aligned with the opening 202 such that the opening, when filled with a conductive material, provides an electrical path to/from the conductive material. For example, the conductive material may be part of a line or via to which the interconnect is coupled.

The opening 202 may be any opening, such as a via, trench, dual damascene structure, or the like. In some embodiments, the opening 202 may have a height to width aspect ratio of at least about 5:1 (e.g., a high aspect ratio). For example, in some embodiments, the aspect ratio may be about 10:1 or greater, such as about 15:1. The opening 202 may be formed by etching the substrate using any suitable etch process. The opening 202 includes a bottom surface 208 and sidewalls 210.

In some embodiments, the sidewalls 210 may be covered with one or more layers prior to depositing metal atoms as described below. For example, the sidewalls of the opening 202 and the first surface 204 of the substrate 200 may be covered by an oxide layer (not shown), such as silicon oxide (SiO₂), silicon carbon nitride, silicon oxicarbide, or the like. The oxide layer may be deposited or grown, for example in a chemical vapor deposition (CVD) chamber or in an oxidation chamber. The oxide layer may serve as an electrical and/or physical barrier between the substrate and one or more of the seed layer or barrier layer materials to be subsequently deposited in the opening, and/or may function as a better surface for attachment during the deposition process discussed below than a native surface of the substrate, and/or may provide a source of oxygen which may be combined with a barrier layer material by annealing or the like to form a final barrier layer and/or barrier layer component of a barrier/seed layer.

In some embodiments, and as illustrated by dotted lines in FIG. 2, the opening 202 may extend completely through the substrate 200 and an upper surface 216 of a second substrate 218 may form the bottom surface 208 of the opening 202. The second substrate 218 may be disposed adjacent to the second surface 206 of the substrate 200. Further (and also illustrated by dotted lines), a conductive material (e.g., 220), for example as part of a device, such as a logic device or the like, or an electrical path to a device requiring electrical connectivity, such as a gate, a contact pad, a conductive line or via, or the like, may be disposed in the upper surface 216 of the second substrate 218 and aligned with the opening 202. In some embodiments, the conductive material 220 aligned with the opening 202 may comprise copper (Cu).

At 104, a layer 222 is formed on the sidewalls 210 and the bottom surface 208 of the opening 202. In some embodiments, the layer 222 may a barrier layer (or first layer) comprising predominantly manganese (Mn) and a seed layer (or second layer) comprising predominantly ruthenium (Ru) or predominantly cobalt (Co) deposited atop the barrier layer (i.e., the layer 222 may comprise two layers). In some embodiments, the layer 222 may comprise a barrier layer material comprising predominantly manganese (Mn) and a seed layer material comprising predominantly ruthenium (Ru) or predominantly cobalt (Co), wherein the barrier and seed layer materials are deposited throughout the thickness of the layer 222 (i.e., the layer 222 may have a varying composition throughout the layer).

Generally speaking, the layer 222 may comprise one or more layers having an overall manganese concentration that is higher adjacent to, or proximate the sidewalls 210 and the bottom surface 208 of the opening 202, and with little or no manganese present in a terminal surface of the layer 222 opposite the sidewalls 210 and the bottom surface 208 of the opening 202. For example, FIG. 2A schematically depicts the manganese content in the layer 222 via line 250. The horizontal portion of line 250 represents little or no manganese in a terminal surface 252 of the layer 222 opposite the sidewalls 210 and the bottom surface 208 of the opening 202. The manganese concentration may increase throughout the layer either gradually (as represented by the inclined profile of the line 250) or in a discontinuous, stepped manner. This may be accomplished in the layer 222 in a number of ways.

For example, the layer 222 may include a first surface 221 adjacent to the sidewall 210 and bottom surface 208 of the opening 202 and a second surface 223 opposite the first surface 221, as illustrated in FIG. 3A. In some embodiments, the second surface 223 may comprise predominantly at least one of ruthenium (Ru) or cobalt (Co). In some embodiments, a predominant quantity of manganese (Mn) in the layer may not be disposed proximate the second surface 223. For example, the layer 222 may comprise about 10-50 percent, or more, of manganese (Mn) proximate the first surface 221 of the layer 222 and may comprise substantially ruthenium (Ru) or cobalt (Co) (e.g., about 50 percent or more) proximate the second surface 223 of the layer 222.

In some embodiments, as depicted in FIG. 3B, the layer 222 may comprise a first layer 302 comprising manganese (Mn) and a second layer 304 comprising at least one of ruthenium (Ru) or cobalt (Co). In some embodiments, the second layer 304 further comprises one of ruthenium (Ru) or cobalt (Co). In some embodiments, the first layer 302 may be deposited on the sidewalls 210 and bottom surface 208 of the opening, for example, as illustrated on the sidewall 210 in FIG. 3B. The second layer 304 may be deposited atop the first layer 302. For example, the first layer 302 may act as a barrier layer and the second layer 304 may act as a seed layer.

In some embodiments, the layer 222 may be annealed to form an oxide layer 303 comprising manganese, silicon, and oxygen at an interface formed between the layer 222 and the surfaces of the opening 202, such as at an interface formed between the first layer 302 and the surface of the side wall 210, as illustrated in FIG. 3C. For example, the oxide layer 303 may be resultant from contributions of materials from the first layer 302, such as manganese (Mn), and silicon and oxygen from the surfaces of the opening 202. For example, the silicon and oxygen may be present due to the presence of a native or deposited layer of silicon oxide, or other oxygen-containing dielectric, as discussed above. In some embodiments, the oxide layer is MnSiₓO_{y}. As a result of oxide layer formation during annealing, some of the ruthenium (Ru) or cobalt (Co) present in the layer 222 at the second layer 304 may become oxidized, which may unfavorably increase resistance of the layer 222 for electroplating purposes. Accordingly, a reducing agent, such as H₂ or the like, may be provided after the annealing process is completed to reduce the oxidized ruthenium (Ru) or cobalt (Co) formed during the anneal. In some embodiments, the substrate may be exposed to an atmosphere comprising H₂ to reduce the oxidized ruthenium (Ru) or cobalt (Co).

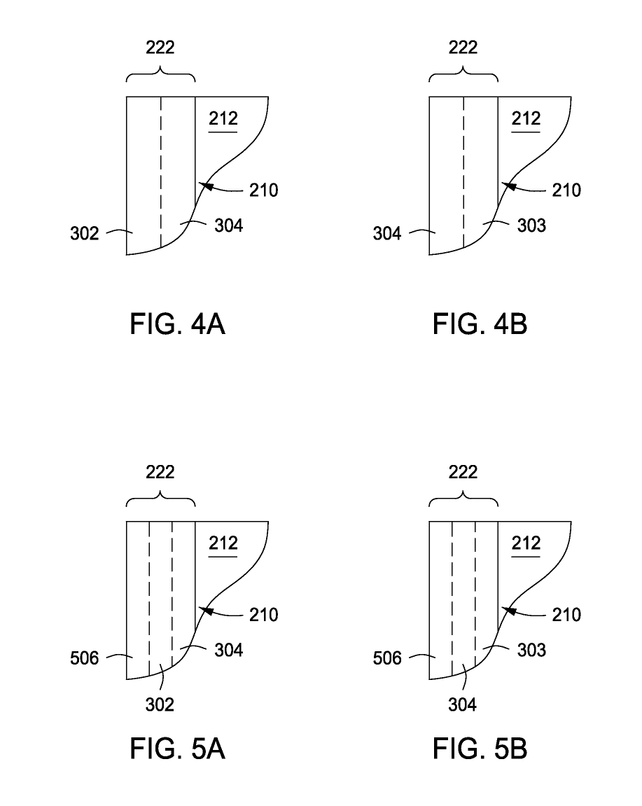

Alternatively, as illustrated in FIGS. 4A-4B, the second layer 304 comprising at least one of ruthenium (Ru) or cobalt (Co) may be deposited on the surfaces of the opening 202, such as the surfaces of the sidewall 210, and the first layer 302 comprising manganese (Mn) may be deposited atop the second layer 304, as illustrated in FIG. 4A. As discussed above, the layer 222 may be annealed to form an oxide layer 303 comprising manganese, silicon, and oxygen at an interface formed between the layer 222 and the surfaces of the opening 202, such as at an interface formed between the second layer 304 and the surface of the side wall 210 as illustrated in FIG. 4B. For example, as illustrated in FIG. 4B, the first layer 302 may be consumed by the annealing process whereby manganese from the first layer 302 may diffuse through the second layer 304 and to the surfaces of the opening 202 to form the oxide layer 303. Similar to what has been discussed above, should the annealing process result in oxidation on the surfaces of the second layer 304, a reducing agent may be utilized to reduce the oxidized ruthenium (Ru) or cobalt (Co) of the second layer 304.

Alternatively, as illustrate in FIGS. 5A-B, a sandwich structure may be used, wherein the second layer 304 may be deposited on the surfaces of the opening 202, the first layer 302 may be deposited atop the second layer 304, and a third layer 506 comprising at least one of ruthenium (Ru) or cobalt (Co) may be deposited atop the first layer 302. The third layer 506 may be the same or different than the first layer 304 in one or more of composition, thickness, or the like. For example, in some embodiments the first and third layers 304, 506 may comprise the same materials, such as one of ruthenium (Ru) or cobalt (Co), in approximately equal concentrations. As discussed above, the layer 222 may be annealed to form the oxide layer 303 comprising manganese, silicon, and oxygen at an interface formed between the layer 222 and the surfaces of the opening 202, such as at an interface formed between the second layer 304 and the surface of the side wall 210 as illustrated in FIG. 5B. For example, as illustrated in FIG. 5B, the first layer 302 may be consumed by the annealing process whereby manganese from the first layer 302 may diffuse through the second layer 304 and to the surfaces of the opening 202 to form the oxide layer 303. However, this illustration of FIG. 5B is merely one exemplary embodiment, and the entirety of the first layer 302 may not necessarily be consumed. Similar to what has been discussed above, should the annealing process result in oxidation on the surfaces of the third layer 506, a reducing agent may be utilized to reduce the oxidized ruthenium (Ru) or cobalt (Co) of the second layer 304.

The layer 222 may be formed by CVD, ALD, or PVD processes. For example, a CVD process may be used to deposit any of the aforementioned embodiments of the layer 222 discussed above. For example, in some embodiments, the CVD process may comprise flowing a manganese-containing gas for a first period of time to deposit the barrier layer (e.g., the first layer 302) and flowing one of a ruthenium-containing gas or a cobalt-containing gas for a second period of time to deposit the seed layer (e.g., the second and/or third layers 304, 506). In some embodiments, the flow of the manganese-containing gas and the ruthenium-containing gas or the cobalt-containing gas may overlap (i.e., be co-flowed) for a third period of time, during which a transitional region of the layer 222 may be deposited. For example, a transition region may be formed at any interface between the first layer 302 and the second and/or third layers 304, 506. Each of the preceding steps may further comprise flowing a reducing agent along with the precursor gas. The reducing agent may comprise, for example, at least one of hydrogen (H₂), ammonia (NH₃), oxygen (O₂), or hydrogen incorporated gases or the like.

In some embodiments, to achieve a graded concentration of the barrier layer material and the seed layer material during the co-flow step above, a ratio of the manganese-containing gas and one of the ruthenium-containing gas or the cobalt-containing gas may be decreased between a beginning and an end of the third period of time. For example, the ratio may be decreased in steps, for example, wherein each step comprises tuning the ratio at a desired value and flowing at that value for a portion of the third period of time. Alternatively, the ratio may be decreased continuously between the beginning and the end of the second period of time. For example, upon or after beginning the flow of the ruthenium-containing gas or the cobalt-containing gas, the flow of the manganese-containing gas may be reduced until it is stopped. In addition, the flow of the ruthenium-containing gas or the cobalt-containing gas may be kept constant or may be increased during the third period of time.

In some embodiments, for example in an ALD process, a reducing agent, as discussed above, may be flowed simultaneously with or alternately with the flow of the manganese-containing gas and the one of the ruthenium-containing gas or the cobalt-containing gas. In addition, the flows of the respective gases may be alternated with a purge gas flow, such that there is a period of deposition followed by a purge of the chamber to define a deposition cycle, and the deposition cycle is repeated as desired to deposit a desired thickness of material to form the layer 222. In some embodiments, the deposition cycle may be maintained or may be varied throughout multiple deposition steps to obtain a film composition through the layer 222 in any of the desired embodiments as discussed above. For example, the deposition cycle may be uniform to deposit a layer 222 having a substantially uniform composition throughout. Alternatively, the deposition cycle may be varied to deposit a layer 222 having a desired composition of manganese and ruthenium or cobalt in various locations throughout the layer 222, as described above.

General processing conditions for any of the CVD or ALD processes discussed above may include any one or more of forming the layer 222 at a temperature ranging from about 100 degrees Celsius to about 400 degrees Celsius, maintaining chamber pressure at about 1 to about 30 Torr, or about 5 to about 10 Torr. The manganese-containing gas may comprise at least one manganese precursor as disclosed in United States Published Patent Application no. 2009/0263965, filed Mar. 20, 2009, by Roy G. Gordon et al., and entitled, “Self-aligned barrier layers for interconnects,” which is hereby incorporated herein by reference in its entirety. The ruthenium-containing gas may comprise at least one of Methyl-cyclohexadine ruthenium (Ru) tricarbonylcyclohexadine, ruthenium (Ru) tricarbonyl, butadiene ruthenium (Ru) tricarbonyl, dimethyl butadiene ruthenium (Ru) tricarbonyl, or modified dines with Ru(CO)₃. The cobalt-containing gas may comprise at least one of a cobalt precursor disclosed in United States Published Patent Application no. 2009/0053426, filed Aug. 29, 2008, by Jiang Lu et al., and entitled, “Cobalt deposition on barrier surfaces,” which is hereby incorporated herein by reference in its entirety.

Alternatively, the layer 222 may be deposited by a PVD process. For example, metal atoms may be sputtered from a target comprising predominantly ruthenium (Ru) or cobalt (Co) and further comprising manganese (Mn) to form the layer 222. For example, the target may comprise one of manganese-ruthenium or manganese-cobalt. In some embodiments, the target may be predominantly ruthenium or predominantly cobalt and may have a manganese content ranging from about 0.1 to about 15 percent. After the metal atoms have been sputtered onto the sidewalls 210 and the bottom surface 208, the layer 222 may be annealed to form the oxide layer 303 as discussed above for any of the embodiments in FIGS. 3-5.

At 106, a conductive material 224 may be deposited to on the layer 222 to fill the opening 202. As discussed above, the conductive material 224 may be deposited by an electroplating or a similar processing technique. The layer 222 may function as a seed layer upon which the conductive material 224 is deposited. The conductive material 224 may include metals, metal alloys, or the like, such as one or more of copper (Cu), aluminum (Al), tungsten (W), or the like. In some embodiments, the conductive material 224 is copper (Cu).

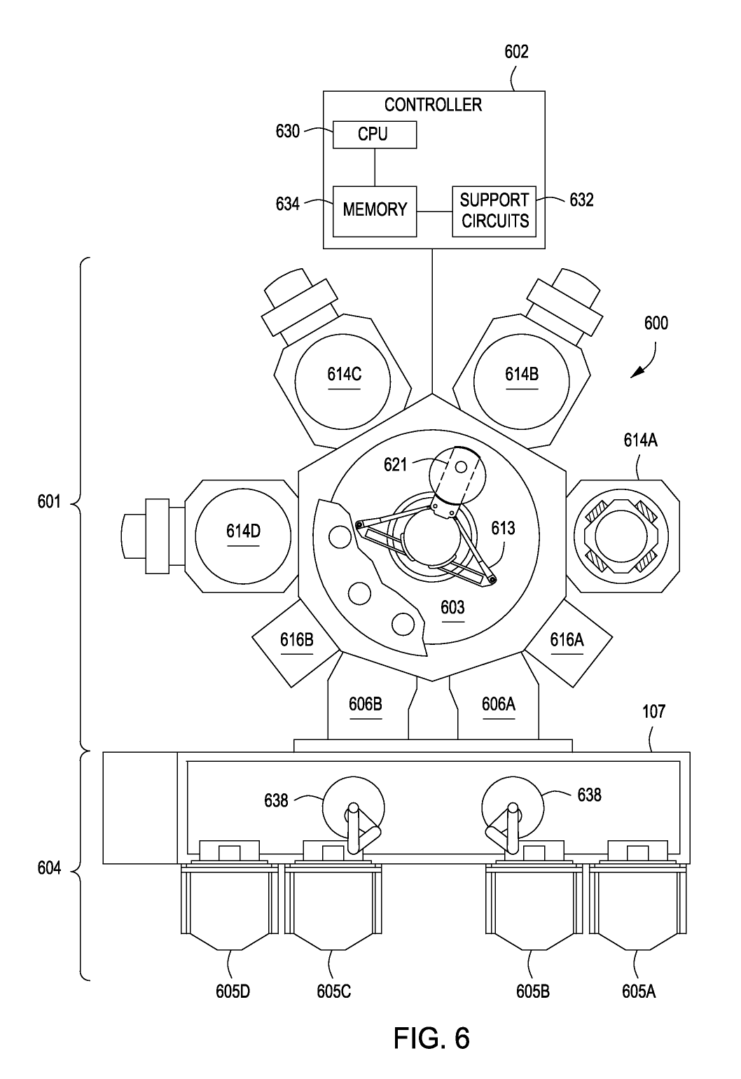

The methods described herein, for example, such as annealing, CVD, PVD processes and the like may be performed in individual process chambers that may be provided in a standalone configuration or as part of a cluster tool, for example, an integrated tool 600 (i.e., cluster tool) described below with respect to FIG. 6. Examples of the integrated tool 600 include the CENTURA® and ENDURA® integrated tools, available from Applied Materials, Inc., of Santa Clara, Calif. It is contemplated that the methods described herein may be practiced using other cluster tools having suitable process chambers coupled thereto, or in other suitable process chambers. For example, it may be advantageous in some embodiments, to perform the inventive methods discussed above in an integrated tool such that there are limited or no vacuum breaks between processing steps. For example, limited or no vacuum breaks may prevent contamination on the seed layer such as oxidation or the like.

The integrated tool 600 includes a vacuum-tight processing platform 601, a factory interface 604, and a system controller 602. The platform 601 comprises multiple processing chambers, such as 614A, 614B, 614C, and 614D operatively coupled to a vacuum substrate transfer chamber 603. The factory interface 604 is operatively coupled to the transfer chamber 603 by one or more load lock chambers (two load lock chambers, such as 606A and 606B shown in FIG. 6).

In some embodiments, the factory interface 604 comprises at least one docking station 607, at least one factory interface robot 638 to facilitate the transfer of the semiconductor substrates. The docking station 607 is configured to accept one or more front opening unified pod (FOUP). Four FOUPS, such as 605A, 605B, 605C, and 605D are shown in the embodiment of FIG. 6. The factory interface robot 638 is configured to transfer the substrates from the factory interface 604 to the processing platform 601 through the loadlock chambers, such as 606A and 606B. Each of the loadlock chambers 606A and 606B have a first port coupled to the factory interface 604 and a second port coupled to the transfer chamber 603. The load lock chamber 606A and 606B are coupled to a pressure control system (not shown) which pumps down and vents the chambers 606A and 606B to facilitate passing the substrates between the vacuum environment of the transfer chamber 603 and the substantially ambient (e.g., atmospheric) environment of the factory interface 604. The transfer chamber 603 has a vacuum robot 613 disposed therein. The vacuum robot 613 is capable of transferring substrates 621 between the load lock chamber 606A and 606B and the processing chambers 614A, 614B, 614C, and 614D.

In some embodiments, the processing chambers 614A, 614B, 614C, and 614D, are coupled to the transfer chamber 603. The processing chambers 614A, 614B, 614C, and 614D comprise at least one of an annealing chamber, a chemical vapor deposition (CVD) chamber, a physical vapor deposition (PVD) chamber or the like. Annealing chambers may include those configured for a plasma oxidation, rapid thermal processes (RTP), radical oxidation or the like. Exemplary CVD and PVD chambers may be plasma or non-plasma, having inductively, capacitively, or remote plasma sources, magnetrons or any suitable configurations for CVD and/or PVD processes known in the art.

In some embodiments, one or more optional service chambers (shown as 616A and 616B) may be coupled to the transfer chamber 603. The service chambers 616A and 616B may be configured to perform other substrate processes, such as degassing, orientation, substrate metrology, cool down and the like.

The system controller 602 controls the operation of the tool 600 using a direct control of the process chambers 614A, 614B, 614C, and 614D or alternatively, by controlling the computers (or controllers) associated with the process chambers 614A, 614B, 614C, and 614D and the tool 600. In operation, the system controller 602 enables data collection and feedback from the respective chambers and systems to optimize performance of the tool 600. The system controller 602 generally includes a Central Processing Unit (CPU) 630, a memory 634, and a support circuit 632. The CPU 630 may be one of any form of a general purpose computer processor that can be used in an industrial setting. The support circuit 632 is conventionally coupled to the CPU 630 and may comprise a cache, clock circuits, input/output subsystems, power supplies, and the like. Software routines, such as a method as described above may be stored in the memory 634, when executed by the CPU 630, transform the CPU 630 into a specific purpose computer (controller) 602. The software routines may also be stored and/or executed by a second controller (not shown) that is located remotely from the tool 600.

Thus, methods for forming barrier/seed layers for interconnect structures have been provided herein. The inventive methods advantageously facilitate improved efficiency, process throughput, and device quality through one or more of reduced barrier/seed layer thickness, reduced barrier/seed layer resistance, or increased deposition rates. The inventive methods may be utilized with any device nodes, but may be particularly advantageous in device nodes of about 22 nm or less. Further, the inventive methods may be utilized with any type of interconnect structure or material, but may be particularly advantageous with interconnect structures formed by electroplating copper (Cu).

While the foregoing is directed to embodiments of the present invention, other and further embodiments of the invention may be devised without departing from the basic scope thereof.

1. A method of processing a substrate having an opening formed in a first surface of the substrate, the opening having a sidewall and a bottom surface, the method comprising:
forming a layer comprising manganese (Mn) and at least one of ruthenium (Ru) or cobalt (Co) on the sidewall and the bottom surface of the opening, the layer having a first surface adjacent to the sidewall and bottom surface of the opening and a second surface opposite the first surface, wherein the second surface comprises predominantly at least one of ruthenium (Ru) or cobalt (Co) and wherein a predominant quantity of manganese (Mn) in the layer is not disposed proximate the second surface; and
depositing a conductive material on the layer to fill the opening.

2. The method of claim 1, wherein the opening has an aspect ratio of height to width of at least 5:1.

3. The method of claim 1, wherein the conductive material is deposited by an electroplating process.

4. The method of claim 3, wherein the conductive material is copper (Cu).

5. The method of claim 1, wherein the layer comprises a first layer and a second layer, and wherein forming the layer further comprises:
depositing the first layer comprising manganese (Mn); and
depositing the second layer comprising at least one of ruthenium (Ru) or cobalt (Co).

6. The method of claim 5, wherein the second layer is deposited on the sidewall and the bottom surface of the opening and the first layer is deposited atop the second layer.

7. The method of claim 6, further comprising:
annealing the layer to form an oxide layer comprising manganese, silicon, and oxygen at an interface between the second layer and the sidewall and bottom surface of the opening.

8. The method of claim 6, wherein depositing the layer further comprises:
depositing a third layer comprising at least one of ruthenium (Ru) or Cobalt (Co) atop the first layer.

9. The method of claim 8, further comprising:
annealing the layer to form an oxide layer comprising manganese, silicon and oxygen at an interface between the second layer and the sidewall and bottom surface of the opening.

10. The method of claim 9, further comprising:
flowing a reducing agent to reduce one of oxidized ruthenium or oxidized cobalt formed on the third layer during the annealing step.

11. The method of claim 5, wherein the first layer is deposited on the sidewall and bottom surface of the opening and the second layer atop the first layer.

12. The method of claim 11, further comprising:
annealing the layer to form an oxide layer comprising manganese, silicon and oxygen at an interface between the layer and the sidewall and bottom surface of the opening

13. The method of claim 12, further comprising:
flowing a reducing agent to reduce one of oxidized ruthenium or oxidized cobalt formed on the second layer during the annealing step.

14. The method of claim 1, wherein depositing the first and second layers further comprises:
(a) flowing a manganese-containing gas for a first period of time; and
(b) flowing at least one of a ruthenium-containing gas or a cobalt-containing gas for a second period of time.

15. The method of claim 14, wherein each of steps (a) and (b) further comprise:
flowing a reducing agent.

16. The method of claim 15, wherein the reducing agent comprises at least one of hydrogen (H₂), ammonia (NH₃), oxygen (O₂), hydrocarbon compounds, or hydrogen incorporated compounds.

17. The method of claim 1, wherein forming the layer further comprises:
forming the layer at a temperature ranging from about 130 to about 350 degrees Celsius.

18. The method of claim 1, wherein the bottom surface of the opening comprises copper (Cu).

19. A method of processing a substrate having an opening formed in a first surface of the substrate, the opening having a sidewall and a bottom surface, the method comprising:
forming a layer comprising manganese (Mn) and one of ruthenium (Ru) or cobalt (Co) on the sidewall and bottom surface of the opening, the layer having a first surface adjacent to the sidewall and bottom surface of the opening and a second surface opposite the first surface, wherein the second surface comprises predominantly one of ruthenium (Ru) or cobalt (Co) and wherein a predominant quantity of manganese (Mn) in the layer is not disposed proximate the second surface; and
depositing a conductive material on the layer to fill the opening.

20. The method of claim 19, wherein forming the layer further comprises:
depositing a first layer comprising manganese (Mn); and
depositing a second layer comprising one of ruthenium (Ru) or cobalt (Co);
depositing a third layer comprising one of ruthenium (Ru) or cobalt (Co), wherein the second layer is deposited on the sidewall and bottom surface of the opening, the first layer is deposited atop the second layer, and the third layer is deposited atop the first layer; and
annealing the first layer to form an oxide layer comprising manganese, silicon and oxygen at an interface between the second layer and the sidewall and bottom surface of the opening.
